(19) United States
(12) Patent Application Publication
(10) Pub. No.: US 2014/0157558 A1
(43) Pub. Date: Jun. 12, 2014

(54) METHOD FOR PREPARING MICRO STRAIGHT PZT PIEZOELECTRIC FIBER ARRAY

(71) Applicants: Caifeng Chen, Jiangsu (CN); Jun Liu, Jiangsu (CN); Ying Luo, Jiangsu (CN)

(72) Inventors: Caifeng Chen, Jiangsu (CN); Jun Liu, Jiangsu (CN); Ying Luo, Jiangsu (CN)

(21) Appl. No.: 13/883,609

(22) PCT Filed: Dec. 31, 2010
(86) PCT No.: PCT/CN2010/080554

§ 371 Date: Jun. 18, 2013

(30) Foreign Application Priority Data
Nov. 26, 2010 (CN) 201010559643.1

(51) Int. Cl. H01L 41/25

(52) U.S. Cl. CPC H01L 41/25
USPC 29/25.35

(57) ABSTRACT

Plastic capillaries are used as a reaction template; firstly, sol-PZT is prepared; then, PZT nanometer powder is added into the sol-PZT and blended uniformly to form suspension, the plastic capillaries are put into a quartz tube, the gaps between the capillaries and the gaps between the quartz tube and the plastic capillaries are filled with paraffin and solidified to a required array shape, the quartz tube is dipped into the suspension, after full absorption, the rest suspension is poured into the quartz tube and filtered from the other end, so that the suspension is pumped into the plastic capillaries until the capillaries are full of suspension. The quartz tube is dried until no excessive liquid component and then taken out to be dipped, filtered and dried; removal of template and crystallization heat treatment is then performed for the dried container.

### TECHNICAL FIELD

The invention relates to functional ceramic fiber and a method of manufacturing it, in particular to a method for preparing micro straight PZT piezoelectric fiber array.

### BACKGROUND

With excellent properties of high piezoelectric strain constant and thickness electromechanical coupling coefficient, low mechanical quality factor and acoustic impedance, etc., the piezoelectric fiber and the array structure thereof have great potential application in sensors, drives and ultrasonic sensor devices, as well as in fields of automobile, aviation and so on.

At present, as common methods for preparing piezoelectric fiber, sol-gel method, extrusion method, spinning method, drawing method, mechanical cutting method, matrix fiber impregnation method and the like have been proposed. For example, the American company “Advanced Cerametrics” prepares PZT fiber which is 80-300 microns in cross-sectional dimension using a suspended magnetic powder spinning method. However, as a great number of organic polymers are used as carriers in this method, which resulted in many gaps between fiber after pyrolysis and sintering, the uniformity of the fiber is decreased; moreover, as the viscosity of the suspension is high, it is hard to control the fiber which is short in diameter. Williams et al. prepare a piezoelectric fiber using a cutting method, the size of the fiber depends on the advanced degree of the machining process as the piezoelectric ceramic is prepared firstly and then cut into fiber in this method. However, at present, it is somewhat difficult to machine the cross-sectional dimension of the fiber to be smaller than 100 microns in diameter. Brei et al. propose to prepare carbon fiber using a template impregnation method, and the fiber prepared by this method has certain intensity and small diameter. However, the fiber is extremely non-straight, and the deformation is obvious. Jiangsu University prepares PZT fiber which is 200-400 microns in diameter using a sol-powder blend extrusion method, and the fiber prepared by this method has higher density. However, the thickness of the fiber is limited by the mould, and it is quite difficult to prepare straight fiber less than 100 microns in diameter.

At present, the piezoelectric fiber array is substantially obtained by a ranking method on the basis of the preparation of the piezoelectric fiber. The method is effective to the array formed by coarse fiber. However, for micro fiber, particularly fiber which is smaller than several hundred microns in diameter, it is easy to cause damage to the fiber and disorder of the array during operation, thus it is rather unfavorable to get the array using the ranking method.

### SUMMARY

One purpose of the invention is to provide a method for preparing a PZT piezoelectric fiber array, which has a single perovskite phase structure, is straight, high in density, 5-100 microns in diameter and in good order, has excellent piezoelectric property, and can be used in sensor/drive devices as 1-3 piezoelectric fiber composites.

The invention relates to a method for preparing a micro straight PZT piezoelectric fiber array, characterized in that plastic capillaries are used as a reaction template. Firstly, sol-PZT is prepared. Then, PZT nanometer powder is added into the sol-PZT and blended uniformly to form suspension. The plastic capillaries are cut into proper length and are put in a container which has two open ends and can be used in the sintering temperature range of the PZT. The gaps between the capillaries and the gaps between the container and the plastic capillaries are filled with paraffin, and they are solidified to a required array shape. The container with the plastic capillaries is dipped into the suspension, after full absorption, the rest suspension is poured into the container from one end thereof and filtered from the other end, so that the suspension with the PZT nanometer powder is pumped into the plastic capillaries until the capillaries are full of suspension. The container with plastic capillaries is dried until there is no excessive liquid component and then taken out to be dipped, filtered and dried for many times. Removal of template and crystallization heat treatment are performed for the dried container with plastic capillaries, thus the PZT piezoelectric fiber array structure is obtained.

The method for preparing a micro straight PZT piezoelectric fiber array is characterized in that the method for preparing sol-PZT is as follows: lead acetate, zirconium nitrate and tetrabutyl titanate are mixed uniformly in the solvent and stabilizer, water and acetic acid are added in to the mixture, the mixture is in interaction under the conditions of low temperature (80 DEG C) heating and ultrasonic vibration and then stirred uniformly on a magnetic stirrer, thus the sol is obtained.

The method for preparing a micro straight PZT piezoelectric fiber array is characterized in that the method for preparing sol-powder mixed system is as follows: the sol-PZT and the PZT nanometer powder are mixed, PEG is added into the mixture as dispersant, the mixture is heated at low temperature (80 DEG C) and stirred uniformly, and the mixture and the sol are mixed fully and uniformly by means of ultrasonic dispersion.

The method for preparing a micro straight PZT piezoelectric fiber array is characterized in that the solvent is ethylene glycol monomethyl ether, and the stabilizer is acetylacetone.

The method for preparing a micro straight PZT piezoelectric fiber array is characterized in that the weight proportion of the sol-PZT and the PZT nanometer powder is 1:0.05-1:0.5; the sol-PZT comprises lead acetate, zirconium nitrate, tetrabutyl titanate, water and acetic acid, the concentration of the sol-PZT is 0.2-1.0 mol/L, wherein the amount proportion of the lead acetate, the zirconium nitrate and the tetrabutyl titanate is 100:(50-60):(40-48), and the weight proportion of the water and the acetic acid is 1:0.5-1:2.

The method for preparing a micro straight PZT piezoelectric fiber array is characterized in that the amount proportion of the lead acetate, the zirconium nitrate and the tetrabutyl titanate is 100:56:44.

The method for preparing a micro straight PZT piezoelectric fiber array is characterized in that the weight proportion of the water and the acetic acid is 1:1.

The method for preparing a micro straight PZT piezoelectric fiber array is characterized in that the concentration of the sol is 0.35 mol/L.

The method for preparing a micro straight PZT piezoelectric fiber array is characterized in that the weight proportion of the sol-PZT and the PZT powder is 1:0.1.

The method for preparing a micro straight PZT piezoelectric fiber array is characterized in that the weight proportion of the PZT nanometer powder and the PEG is 1:0.001-1:0.008.

The method for preparing a micro straight PZT piezoelectric fiber array is characterized in that the weight proportion of the PZT nanometer powder and the PEG is: 1:0.005.

The method for preparing a micro straight PZT piezoelectric fiber array is characterized in that the process of removal of template and crystallization heat treatment is as follows: for the range of room temperature to 200 DEG C, the heating rate is 1 DEG C/min, and the temperature is kept at 200 DEG C for 1 h; for the range of 200 DEG C to 600 EG C, the heating rate is 2 DEG C/min, and the temperature is kept at 600 DEG C for 1-2 h; for the range of 600 DEG C to 950 DEG C, the heating rate is 3.5 DEG C/min, and the temperature is kept at 950 DEG C for 30 min.

The method for preparing a micro straight PZT piezoelectric fiber array is characterized in that the container is a quartz tube.

Compared with the existing preparation methods, the invention has the outstanding advantages that: in this method, the diameter and length of the fiber can be controlled precisely, and, straight and high-density micro PZT piezoelectric fiber which is several microns to hundred microns in diameter and 0.5 cm-3 cm in length can be prepared. The PZT piezoelectric fiber has a single perovskite phase structure, with smooth surface and high piezoelectric property; and the piezoelectric fiber prepared by this method can directly form various required array structures without manual arrangement, and the arrangement of the fiber is in good order with little damage.

### BRIEF DESCRIPTION

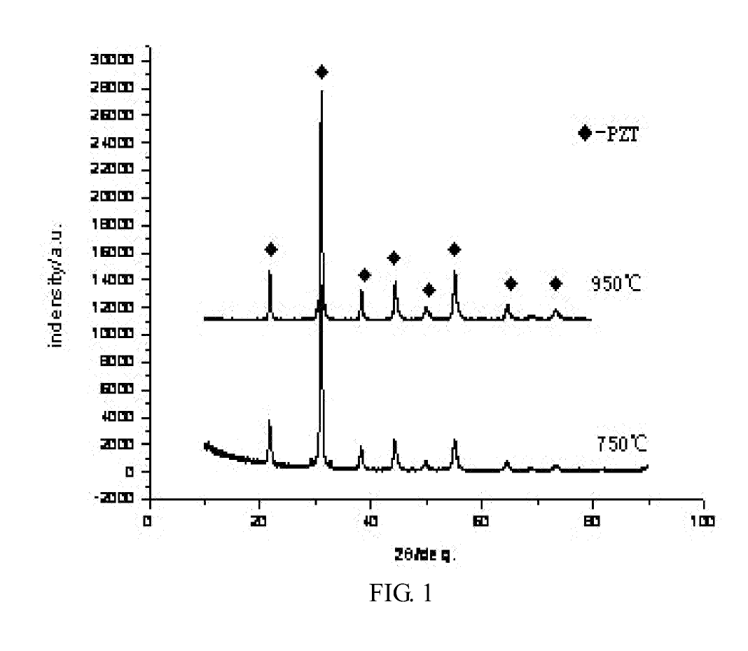

FIG. 1 is an X-ray diffraction spectrogram of the PZT piezoelectric fiber sintered at two different temperatures of 750 DEG C and 950 DEG C. In FIG. 1, the X-axis is the diffraction angle, and the Y-axis is the diffraction intensity. FIG. 1 shows that the fiber has a single perovskite phase after sintered at 950 DEG C.

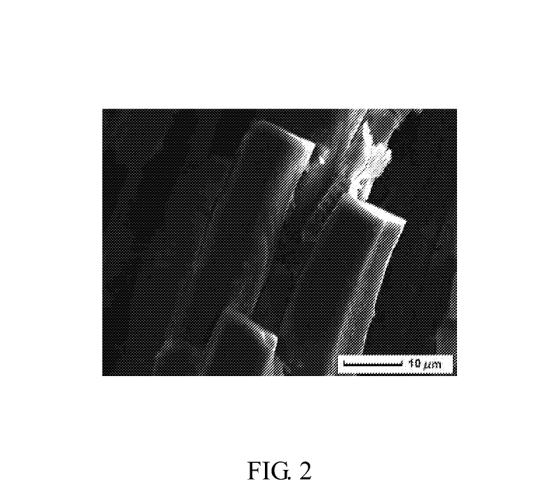

FIG. 2 is a scanning electron micrograph of the PZT piezoelectric fiber sintered at 950 DEG C, in FIG. 2, the morphology of the fiber shows that the fiber is compact without pores.

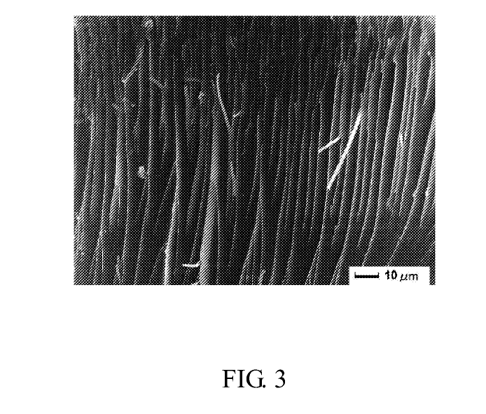

FIG. 3 is a scanning electron micrograph of the PZT piezoelectric fiber sintered at 950 DEG C, in FIG. 3, the fiber is in good order with little damage.

### DETAILED DESCRIPTION

The PZT piezoelectric fiber and the array structure thereof designed by the invention are characterized in that plastic capillaries are used as templates, and the micro straight PZT ceramic fiber array is prepared adopting the mixed absorption and reaction method of the sol and the PZT nanometer powder.

Wherein, the proportion of the sol and the PZT nanometer powder is 1:0.05-1:0.5; the sol comprises lead acetate, zirconium nitrate, tetrabutyl titanate, water and acetic acid, the concentration of the sol is 0.2-1.0 mol/L, wherein the proportion of the lead acetate, the zirconium nitrates and the tetrabutyl titanate is 100:(50-60):(40-48), the proportion of the water and the acetic acid is 1:0.5-1:2.

The method for preparing the PZT piezoelectric fiber is conducted according to the following processes:

1. Preparation of the sol-PZT: the proportional lead acetate, zirconium nitrate and tetrabutyl titanate are added in the solvent and stabilizer, and then mixed with the proportional water and acetic acid. The mixture is mixed uniformly under the conditions of low temperature (80 DEG C) heating and ultrasonic vibration, then stirred uniformly on a magnetic stirrer, and finally hydrolyzed completely, thus the sol is obtained;

2. Preparation of the sol-powder mixed system: the sol and the PZT nanometer powder are mixed according to above proportion, PEG is added into the mixture as dispersant, the mixture is heated at low temperature (80 DEG C) and stirred uniformly by means of magnetic stirring and ultrasonic dispersion.

3. Preparation of the PZT piezoelectric fiber: plastic capillaries are cut into proper length. The gaps between the capillaries are filled with paraffin, solidified to a required array shape, and put in a quartz tube. The gaps between the quartz tube and plastic capillaries are filled with paraffin. The quartz tube with plastic capillaries is dipped into the suspension. After full absorption, the suspension is slowly poured into the quartz tube from the upper part thereof and filtered from the lower part, so that the PZT nanometer powder is pumped into plastic capillaries until the capillaries are full of the powder particles. The quartz tube and plastic capillaries are put into an oven to be dried at 60 DEG C until there is no excessive liquid component, and then taken out to be dipped, filtered and dried for many times.

4. Heat treatment of the PZT piezoelectric fiber: the dried quartz tube and the plastic capillaries with fiber are put into a heat treatment furnace for removal of template and crystallization heat treatment, thus the PZT piezoelectric fiber array structure is obtained.

In the sol of the PZT piezoelectric fiber and the method for manufacturing a PZT piezoelectric fiber array structure, the solvent is ethylene glycol monomethyl ether, and the stabilizer is acetylacetone.

According to the method for manufacturing a PZT piezoelectric fiber array, the proportion of the lead acetate, the zirconium nitrate and the tetrabutyl titanate is 100:(50-60):(40-48), the optimal proportion is 100:56:44; in the sol-powder system, the powder is PZT nanometer powder, such as PZT nanometer powder, where Zr:Ti=56:44.

According to the method for manufacturing PZT piezoelectric fiber, the proportion of the water and the acetic acid is 1:0.5-1:2, and the optimal proportion is 1:1. If the proportion is too large, as the content of the water is too high, the hydrolysis speed of the sol is quite quick to form gel, losing the liquidity; and vice versa, if the proportion is too small, the content of the acetic acid is too high, although it is favorable to restrain the hydrolysis, the acetic acid will volatilize in the process of drying and sintering, thus enlarging the shrinkage of the fiber, meanwhile, a large number of gaps will be left, and the density and intensity of the fiber are decreased. Thus the proportion of the water and the acetic acid is required to be within the range.

According to the method for manufacturing PZT piezoelectric fiber, the concentration of the sol is 0.2-1.0 mol/L, and the optimal concentration is 0.35 mol/L. If the concentration is too high, the viscosity of the sol is too large, and the PZT nanometer powder is hard to disperse; if the viscosity is too low, the density of the prepared fiber will be influenced. Therefore, the viscosity of the sol is required to be within a certain range.

According to the method for manufacturing PZT piezoelectric fiber, the proportion of the sol and the PZT powder is 1:0.05-1:0.5, and the optimal proportion is 1:0.1. When the proportion is too high, the content of the solid phase is quite low and the viscosity is too low, thus the formed fiber is easy to deform. And vice versa, if the proportion is too low, the liquidity of the sol-powder system is poor, thus templates are easy to be blocked. Therefore, the proportion of the sol and the PZT powder is required to be within the range.

In the invention, the weight proportion of the PZT nanometer and the PEG is 1:0.0001-1:0.008, and the optional proportion is 1:0.005. When the proportion is too large, micelles are formed easily, which is unfavorable for the nanometer powder to disperse in the sol. When the proportion is too small, it is hard to achieve the purpose of dispersing the powder well. Therefore, the proportion of the powder and the PEG is required to be within the range.

According to the method for manufacturing PZT piezoelectric fiber, the process of the heat treatment is as follows: 1. for the range of room temperature to 200 DEG C, the heating rate is 1 DEG C/min, and the temperature is kept at 200 DEG C for 1 h, mainly involving the volatilization of water and partial organics in the fiber precursor; 2. for the range of 200 DEG C to 600 DEG C, the heating rate is 2 DEG C/min, and the temperature is kept at 600 DEG C for 1-2 h, mainly involving the volatilization and decomposition of organics and the crystallization of the PZT fiber; 3. for the range of 600 DEG C to 900 DEG C, the heating rate is 3.5 DEG C/min, mainly involving the growth of crystal grains, the densification of the fiber and the elimination of the gaps, and the temperature is kept at 950 DEG C for 30 min.

Several specific embodiments of the invention are given below.

### Embodiment 1

Three materials, namely lead acetate, zirconium nitrate and tetrabutyl titanate, are weighed according to the mol proportion of 100:56:44, and dissolved and blended uniformly with the ethylene glycol monomethy ether. Then water and acetic acid with the proportion of 1:1 are added into the mixture. The concentration of the solution is adjusted to be 0.3 mol/L by means of magnetic stirring to obtain sol. Ten portions of the sol are measured, one portion of PZT nanometer powder is weighed according to the weight proportion of the sol and the PZT powder of 1:0.1, and PEG1000, the amount of which is 0.5% of the PZT nanometer powder, is then added into the mixture. The mixture is dispersed by means of magnetic stirring for half an hour and then put into an ultrasonic disperser to be dispersed for 2 h, thus the sol-powder system is prepared. The thin-wall plastic capillaries, the inner diameter of which is 0.25 mm, are cut into 2 cm in length. 50 plastic capillaries are ranged in a circular section array shape. The gaps between the capillaries are filled with paraffin. The capillaries are put into a quartz tube which is 1 cm in inner diameter and solidified at room temperature for 30 min. The gaps between the quartz tube and the plastic capillaries are sealed by little paraffin. The quartz tube with the plastic capillaries is dipped into the suspension which is obtained by blending the sol and the powder. After full absorption, the suspension is poured slowly into the quartz tube from the upper part thereof and filtered from the lower part, so that the PZT nanometer powder is pumped into the plastic capillaries until the capillaries are full of powder particles. The quartz tube and the plastic capillaries are put into an oven to be dried at 60 DEG C until there is no excessive liquid component and then taken out to be dipped, filtered and dried for three times. The quartz tube, with the plastic capillaries which contain the fiber, is put into a heat treatment furnace to be calcined to 950 DEG C for removal of the templates and sintering. The PZT piezoelectric fiber which is about 50 microns in average diameter and about 0.8 cm in length and the structure in which the fiber is ranked in a circular section array in order are obtained.

### Embodiment 2

Three materials, namely lead acetate, zirconium nitrate and tetrabutyl titanate, are weighed according to the mol proportion of 100:56:44, and dissolved and blended uniformly with the ethylene glycol monomethy ether. Then water and acetic acid with the proportion of 1:1 are added into the mixture. The concentration of the solution is adjusted to be 0.5 mol/L by means of magnetic stirring to obtain sol. One hundred portions of the sol are measured, and six portions of PZT nanometer powder are weighed according to the weight proportion of the sol and the PZT powder of 1:0.06, and PEG400 and PEG2000, the amount of which is 0.6% of the PZT nanometer powder, are then added into the mixture. The mixture is dispersed by means of magnetic stirring for half an hour and then put into an ultrasonic disperser to be dispersed for 2 h, thus the sol-powder system is prepared. The thin-wall plastic capillaries, the inner diameter of which is 0.3 mm, are cut into 4 cm in length. 100 plastic capillaries are ranged in a circular section array shape. The gaps between the capillaries are filled with paraffin. The capillaries are put into a quartz tube which is 2 cm in inner diameter and solidified at room temperature for 6 h. The gaps between the quartz tube and the plastic capillaries are sealed by little paraffin. The quartz tube with the plastic capillaries is dipped into the suspension which is obtained by blending the sol and the powder. After full absorption, the suspension is poured slowly into the quartz tube from the upper part thereof and filtered from the lower part, so that the PZT nanometer powder is pumped into the plastic capillaries until the capillaries are full of powder particles. The quartz tube and the plastic capillaries are put into an oven to be dried at 60 DEG C until there is no excessive liquid component and then taken out to be dipped, filtered and dried for three times. The quartz tube, with the plastic capillaries which contain the fiber, is put into a heat treatment furnace to be calcined to 1000 DEG C for removal of the templates and adhesive and sintering. The PZT piezoelectric fiber which is about 80 microns in average diameter and about 1.5 cm in length and the structure in which the fiber is ranked in a circular section array in order are obtained.

### Embodiment 3

Three materials, namely lead acetate, zirconium nitrate and tetrabutyl titanate, are weighed according to the mol proportion of 100:56:44, and dissolved and blended uniformly with the ethylene glycol monomethy ether. Then water and acetic acid with the proportion of 1:1 are added into the mixture. The concentration of the solution is adjusted to be 0.35 mol/L by means of magnetic stirring to obtain sol. Ten portions of the sol are measured, four portions of PZT nanometer powder are weighed according to the weight proportion of the sol and the PZT powder of 1:0.4, and PEG1000, the amount of which is 0.5% of the PZT nanometer powder, is then added into the mixture. The mixture is dispersed by means of magnetic stirring for half an hour and then put into an ultrasonic disperser to be dispersed for 2 h, thus the sol-powder system is prepared. The thin-wall plastic capillaries, the inner diameter of which is 0.1 mm, are cut into 2 cm in length. 49 plastic capillaries are ranged in a 7*7 square array shape. The gaps between the capillaries are filled with paraffin. The capillaries are put in a quartz tube which is 4 cm in inner diameter and solidified at room temperature for 6 h. The gaps between the quartz tube and the plastic capillaries are sealed by little paraffin. The quartz tube with the plastic capillaries is dipped into the suspension which is obtained by blending the sol and the powder. After full absorption, the suspension is poured slowly into the quartz tube from the upper part thereof and filtered from the lower part, so that the PZT nanometer powder is pumped into the plastic capillaries until the capillaries are full of powder particles. The quartz tube and the plastic capillaries are put into an oven to be dried at 60 DEG C until there is no excessive liquid component and then taken out to be dipped, filtered and dried for three times. The quartz tube, with the plastic capillaries which contain the fiber, is put into a heat treatment furnace to be calcined to 950 DEG C for removal of the templates and adhesive and sintering. The square PZT piezoelectric fiber array structure which is about 30 microns in average diameter and about 0.8 cm in length is obtained.

1. A method for preparing a micro straight PZT piezoelectric fiber array, wherein a plurality of plastic capillaries are used as a reaction template, comprising:
preparing sol-PZT;
adding a PZT nanometer powder into the sol-PZT and uniformly blending to form a suspension;
cutting the plurality of plastic capillaries into proper length and putting in a container which has two open ends, the container configured to be used in a sintering temperature range of the PZT, wherein a gap between the plurality of plastic capillaries and the gap between the container and the plurality of plastic capillaries are filled with paraffin and are solidified to a required array shape;
dipping the container with the plurality of plastic capillaries into the suspension, and after full absorption, a rest suspension is poured into the container from one end thereof and filtered from the other end, so that the suspension with the PZT nanometer powder is pumped into the plurality of plastic capillaries until the plurality of plastic capillaries are full of suspension; and
drying the container with plastic capillaries until there is no excessive liquid component and then taking out to be dipped, filtered and dried for many times, wherein removal of the template and crystallization heat treatment are performed for the dried container with the plurality of plastic capillaries.

2. The method for preparing a micro straight PZT piezoelectric fiber array according to claim 1, wherein the method for preparing sol-PZT is as follows: uniformly mixing lead acetate, zirconium nitrate and tetrabutyl titanate in a solvent and a stabilizer, and adding water and acetic acid in to the mixtures, the mixtures are in interaction under the condition of low temperature (80 DEG C) heating and ultrasonic vibration and then stirred uniformly on a magnetic stirrer.

3. The method for preparing a micro straight PZT piezoelectric fiber array according to claim 1, wherein the method for preparing sol-powder mixed system is as follows: mixing the sol-PZT and the PZT nanometer powder, wherein PEG is added into the mixtures as dispersant, the mixtures are heated at low temperature (80 DEG C) and stirred uniformly, and the mixtures and the sol are mixed fully uniformly by means of ultrasonic dispersion.

4. The method for preparing a micro straight PZT piezoelectric fiber array according to claim 2, wherein the solvent is ethylene glycol monomethyl ether, and the stabilizer is acetylacetone.

5. The method for preparing a micro straight PZT piezoelectric fiber array according to claim 1, wherein the weight proportion of the sol-PZT and the PZT nanometer powder is 1:0.05-1:0.5; the sol-PZT comprises lead acetate, zirconium nitrate, tetrabutyl titanate, water and acetic acid, the concentration of the sol-PZT is 0.2-1.0 mol/L, wherein the amount proportion of the lead acetate, the zirconium nitrate and the tetrabutyl titanate is 100:(50-60):(40-48), and the weight proportion of the water and the acetic acid is 1:0.5-1:2.

6. The method for preparing a micro straight PZT piezoelectric fiber array according to claim 5, wherein the amount proportion of the lead acetate, the zirconium nitrate and the tetrabutyl titanate is 100:56:44, the weight proportion of the water and the acetic acid is 1:1, the concentration of the sol is 0.35 mol/L, and the weight proportion of the sol-PZT and the PZT powder is 1:0.1.

7. The method for preparing a micro straight PZT piezoelectric fiber array according to claim 3, wherein the weight proportion of the PZT nanometer powder and the PEG is 1:0.001-1:0.008.

8. The method for preparing a micro straight PZT piezoelectric fiber array according to claim 7, wherein the weight proportion of the PZT nanometer powder and the PEG is: 1:0.005.

9. The method for preparing a micro straight PZT piezoelectric fiber array according to claim 1, wherein the process of removal of template and crystallization heat treatment is as follows: for the range of room temperature to 200 DEG C, the heating rate is 1 DEG C/min, and the temperature is kept at 200 DEG C for 1 h; for the range of 200 DEG C to 600 DEG C, the heating rate is 2 DEG C/min, and the temperature is kept at 600 DEG C for 1-2 h; for the range of 600 DEG C to 950 DEG C, the heating rate is 3.5 DEG C/min, and the temperature is kept at 950 DEG C for 30 min.

10. The method for preparing a micro straight PZT piezoelectric fiber array according to claim 1, wherein the container is a quartz tube.
